(19) United States
(12) Patent Application Publication
(10) Pub. No.: US 2012/0185191 A1
(43) Pub. Date: Jul. 19, 2012

(54) PORTABLE EQUIPMENT, NOTIFICATION METHOD AND NOTIFICATION PROGRAM

(76) Inventor: Takayuki Sugaya, Tokyo (JP)

(21) Appl. No.: 13/498,223

(22) PCT Filed: Sep. 27, 2010
(86) PCT No.: PCT/JP2010/066679

§ 371 Date: Mar. 26, 2012

(30) Foreign Application Priority Data
Oct. 2, 2009 (JP) 2009-230203

(51) Int. Cl. G01R 31/36; G06F 19/00

(52) U.S. Cl. 702/63

(57) ABSTRACT

A portable equipment (100) performs a predetermined process by being driven by a secondary battery (219). A remaining amount detection part (240) detects a battery remaining amount of said secondary battery. A consumption current computing part (120) computes an average value of a consumption current consumed to perform the predetermined process. A processing amount computing part (130) computes an executable process amount of the predetermined process based on the detected battery remaining amount and the computed average value of the consumption current. The notification part (150) notifies a user of the portable equipment (100) of the computed executable process amount of the predetermined process.

### TECHNICAL FIELD

The present invention relates to portable equipments driven by a secondary battery that is chargeable and dischargeable.

### BACKGROUND ART

In recent years, with miniaturization in electronic equipment, portable equipment driven by a secondary battery (may also be referred to as a rechargeable battery) such as a lithium ion battery, etc., have become widely used. The portable equipment include, for example, a cellular phone, a digital camera, a music player, a DVD (Digital Versatile Disc) player, etc.

In many portable equipments driven by a battery, a remaining battery power is displayed on a display or the like in order to avoid the portable equipment from becoming unusable due to battery exhaustion. A user of such a portable equipment can use the portable equipment while recognizing the remaining battery power by viewing the display. For example, Patent Document 1 discloses a portable printer having a display panel to display an amount of remaining battery power.

### PRIOR ART DOCUMENT

### Patent Document

Patent Document 1: Japanese Laid-Open Patent Application No. 2005-297477

### SUMMARY

However, the portable printer disclosed in the above-mentioned Patent Document 1 can detect remaining battery power with only three levels, and cannot detect an accurate remaining amount of a secondary battery. Thereby, it is difficult to notify a user of an appropriate timing to charge the secondary battery.

The present invention was made in view of the the above-mentioned situation to solve these problems, and it is a main object to provide portable equipment that can prompt a user to charge a secondary battery at an appropriate timing.

### Means to Solve the Problems

According to one aspect of the present invention, there is provided a portable equipment that performs a predetermined process by being driven by a secondary battery, comprising: a remaining amount detection part that detects a battery remaining amount of the secondary battery; a consumption current computing part that computes an average value of a consumption current consumed to perform the predetermined process; a processing amount computing part that computes an executable process amount of the predetermined process based on the battery remaining amount detected by the remaining amount detection part and the average value of the consumption current computed by the consumption current computing part; and a notification part that notifies a user of the portable equipment of the executable process amount of the predetermined process computed by the process amount computing part.

There is provided according to another aspect of the present invention a notification method performed by a portable equipment that performs a predetermined process by being driven by a secondary battery, comprising:

a remaining amount detecting step of detecting a battery remaining amount of the secondary battery; a consumption current computing step of computing an average value of a consumption current consumed to perform the predetermined process; a processing amount computing step of computing an executable process amount of the predetermined process based on the detected battery remaining amount and the computed average value of the consumption current; and a notifying step of notifying a user of the portable equipment of the executable process amount of the predetermined process computed by the process amount computing part.

Additionally, there is provided according to another aspect of the present invention a computer readable notification program that causes a portable equipment to perform the above-mentioned notification method.

### Effect of the Invention

According to the present invention, it can prompt a user to charge a secondary battery at an appropriate timing.

### BRIEF DESCRIPTION OF THE DRAWINGS

FIG. 1 is a block diagram illustrating a hardware structure of portable equipment according to a first embodiment.

FIG. 2 is a block diagram illustrating a functional structure of the portable equipment according to the first embodiment.

FIG. 3 is a flowchart of a process of computing an average value of consumption current.

FIG. 4 is a flowchart of a process of displaying an executable process amount.

FIG. 5 is a circuit diagram of a battery pack mounted in the portable equipment.

FIG. 6 is a block diagram illustrating a hardware structure of a monitor IC.

FIG. 7 is a block diagram illustrating a functional structure of a remaining amount detection part of the monitor IC.

FIG. 8 is a block diagram of portable equipment according to a second embodiment.

FIG. 9 is a block diagram of portable equipment according to a third embodiment.

FIG. 10 is a block diagram of portable equipment according to a fourth embodiment.

FIG. 11 is a view illustrating a screen to notify of an executable process amount in a fifth embodiment.

FIG. 12 is a view illustrating a screen to notify of an executable process amount in a sixth embodiment.

FIG. 13 is a block diagram for explaining a functional structure of a DVD player according to a seventh embodiment.

FIG. 14 is a view illustrating a screen to notify of an executable process amount in a seventh embodiment.

FIG. 15 is a view illustrating a screen to notify of an executable process amount in an eighth embodiment.

FIG. 16 is a block diagram illustrating a functional structure of a portable navigation device according to a ninth embodiment.

FIG. 17 is a view illustrating a screen to notify of an executable process amount in the ninth embodiment.

FIG. 18 is a view illustrating a game machine having a controller according to a tenth embodiment.

FIG. 19 is a block diagram illustrating a hardware structure of the controller according to the tenth embodiment.

FIG. 20 is a block diagram illustrating a body and the controller according to the tenth embodiment.

FIG. 21A is a perspective view of an audio data output device according to an eleventh embodiment.

FIG. 21B is a perspective view of an audio data output device according to an eleventh embodiment.

FIG. 22 is a block diagram illustrating a hardware structure of a reception device according to the eleventh embodiment.

FIG. 23 is a block diagram illustrating a hardware structure according to the eleventh embodiment.

FIG. 24 is a block diagram illustrating a function of the audio data output device according to the eleventh embodiment.

### DETAILED DESCRIPTION OF THE PREFERRED EMBODIMENTS

According to the embodiments explained below, a user is prompted to charge a secondary battery at an appropriate timing by computing using portable equipment an executable amount of process based on a remaining power of the secondary battery, and then notify the user of a computed amount of process.

### First Embodiment

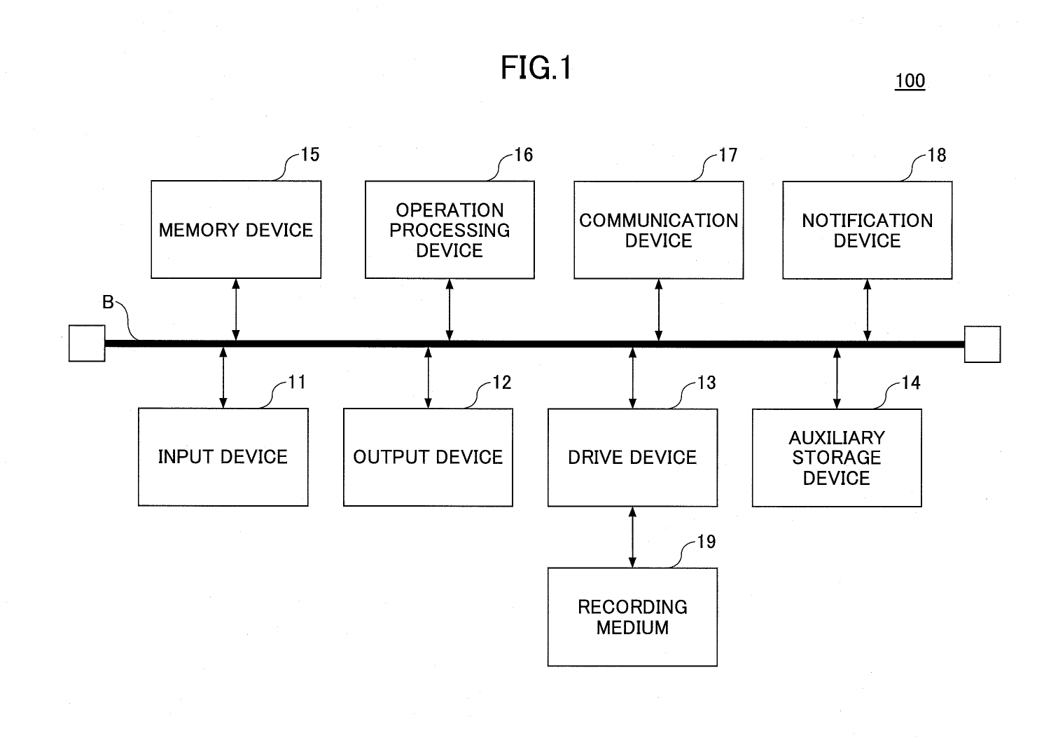

FIG. 1 is a view illustrating an example of a hardware structure of a first portable equipment. The portable equipment 100 of the present embodiment includes an input device 11, an output device 12, a drive device 13, an auxiliary storage device 14, a memory device 15, an operation processing device 16, a communication device 17, and a notification device 18, which are mutually connected through a bus B.

The input device 11 is a device for inputting data to the portable equipment 100. The input device 11 can be an operation button such as, for example, a power supply key and ten keys, and the data input to the portable equipment 100 may be, for example, various kinds of signals for operating the portable equipment 100. The input device 11 may be, for example, an device that inputs data from outside, which data is to be processed by the portable equipment 100 and output from the output device.

The output device 12 is a device for outputting input data. The output device 12 is, for example, a liquid crystal display or the like, and a guidance screen for guiding an operation of the portable equipment 100 and a progress of a process executed by the portable equipment 100 may be displayed. Moreover, the output device 12 may be, for example, a device which outputs data to outside which data is processed data input from the input device 11.

The communication device 17 is a device with which the portable equipment 100 communicates with other devices. Specifically, the communication device 17 is, for example, an antenna or the like provided in the portable equipment 100. Moreover, for example, the communication device 17 carries out a process for transmitting and receiving data through the antenna.

The notification device 18 is a device for notifying of a device condition of the portable equipment 100. The device condition represents, for example, a usable time, an executable amount of process, etc., of the portable equipment 100. Specifically, the notification device 18 may be a device to output sound or voice, a device to output buzzer sound, or may be a device to display messages.

A display control program is at least a part of various kinds of programs that controls the portable equipment 100. The display control program is provided by distribution of a recording medium 19, reception through the communication device 17, etc. The recording medium 19 is a recording medium such as, for example, a memory card which is readable by the portable equipment 100.

When the recording medium 19, which records the display control program, is set in the drive device 13, the display control program is installed in the auxiliary storage device 14 from the recording medium 19 through the drive device 13. The display control program received through the communication device 17 is installed in the auxiliary storage device 14.

The auxiliary storage device 14 stores the installed display control program, and also stores necessary files and data. The memory device 15 reads from the auxiliary storage device 14 the display control program at a time of activating the portable equipment 100 and develops it. Then, the operation processing device 16 various kinds of processes as mentioned later in accordance with the display control program developed on the memory device 15.

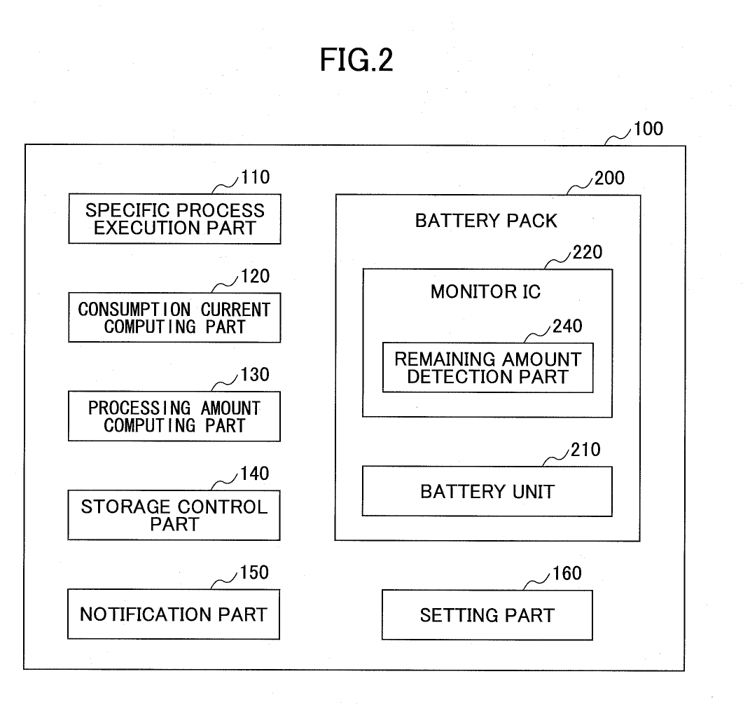

Next, a description will be given, with reference to FIG. 2, of a functional structure of the portable equipment 100 of the present embodiment. FIG. 2 is a block diagram illustrating the functional structure of the portable equipment of the first embodiment. A battery pack 200 is built in the portable equipment 100 according to the present embodiment. The portable equipment 100 operates by being supplied with electric power from a battery unit 210 provided in the battery pack 200.

The battery pack 200 has a monitor IC 220 which monitors a state of the battery unit 210. The monitor IC 220 has a remaining amount detection part 240 which detects a remaining battery power of the battery unit 210. A description of the battery pack 200 will be mentioned later in detail.

The portable equipment 100 according to the present embodiment has a specific process execution part 110, a consumption current computing part 120, a processing amount computing part 130, a storage control part 140, a notification part 150 and a setting part 160.

The specific process execution part 110 executes a specific process which is executable by the portable equipment 100. The consumption current computing part 120 computes an average value of a consumption current during execution of process by the specific execution part 110. The processing amount computing part 130 computes an amount of process executable by the specific process execution part 110 based on a remaining battery power of the battery unit 210.

When the portable equipment 100 according to the present embodiment is, for example, a portable printing device, the specific process execution part 110 performs a printing process. The consumption current computing part 120 computes an average value of the consumption current during execution of the printing process. The processing amount computing part 130 computes an amount of printings which is executable. The amount of printings may be a number of characters which can be printed, or may be a number of sheets of paper which can be printed.

For example, when the portable equipment 100 according to the present embodiment is a digital camera, the specific process execution part 110 performs a photography process. The consumption current computing part 120 computes an average value of consumption current during execution of the photography process. The processing amount computing part 130 computes an amount of photographs which can be performed. The amount of photographs may be a number of pictures which can be photographed.

The storage control part 140 stores in the memory device 15 an average value of the consumption current computed by the consumption current computing part 120 and an amount of executable process of the specific process execution part 110 computed by the processing amount computing part 130. The notification part 150 reads the amount of executable process stored in the memory device 15, etc., by the storage control part 140, and causes the notification part 18 to send a notification.

The setting part 160 sets whether to perform the notification by the notification device 18. Specifically, if a notification of executable process amount is set by, for example, the input device 11 or the like, the setting part 160 sets and stores the setting in the memory device 15 or the like.

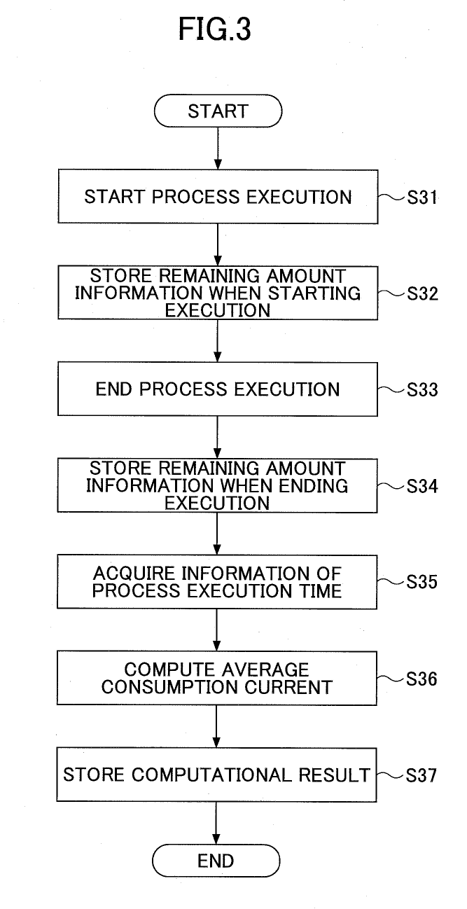

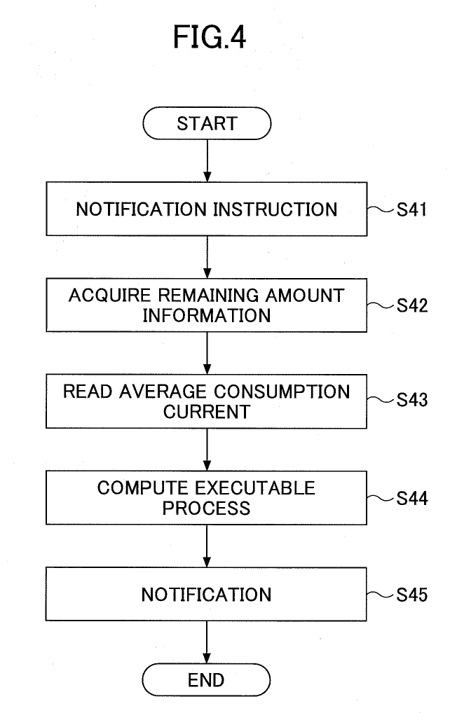

Next, a description will be given, with reference to FIG. 3 and FIG. 4, of an operation of the portable equipment 100 of the present embodiment. FIG. 3 is a flowchart of a process of computing an average value of a consumption current in the portable equipment of the first embodiment. The process mentioned below is performed when the setting of a notification of an amount of process executable by the setting part 160 is made.

When execution of the process by the specific process execution part 110 is started (step S31), the consumption current computing part 120 acquires remaining amount information from the battery pack 200 (step S32). The acquired remaining amount information is stored in the memory device 15, etc., by the storage control part 140.

After the execution of the process by the specific process execution part 110 is ended (step S33), the consumption current computing part 120 acquires the remaining amount information from the battery pack 200 again (step S34). The acquired remaining amount information is stored in the memory device 15, etc., by the storage control part 140. Then, the consumption current computing part 120 acquires information regarding the execution time of the process by the specific process execution part 110 (step S35). The execution time of the process is measured by a time counting function, which is not illustrated in the figure, of the portable equipment 100.

The consumption current computing part 120 computes an average consumption current at the time of execution by the specific process execution part 110 based on the stored remaining amount information at the time of starting the execution of the process, the stored remaining amount information at the time of ending the execution of the process, and the stored information regarding the execution time of the process (step S36). The computed average consumption current is stored in the memory device 15, etc., by the storage control part 140 (step S37).

In the portable equipment according to the present embodiment, the average consumption current changes depending on, for example, an amount of data handled at the time of executing a process. Therefore, it is desirable that the consumption current computing part 120 of the present embodiment periodically performs the computation of the average consumption current at the time of execution of the process.

Next, a description will be given, with reference to FIG. 4, of a process of notifying of an executable process amount in the portable equipment 100. FIG. 4 is a flowchart of a process of displaying an executable process amount in the portable equipment 100 according to a first embodiment.

When an instruction is made by the input device 11 of notification of an executable process (step S41), the processing amount computing part 130 acquires remaining amount information from the battery pack 200 (step S42). Then, the processing amount computing part 130 reads the average consumption current at the time of execution of the process stored in the memory device (step S43)

Then, the processing amount computing part 130 computes the computed executable process amount of the process based on the acquired remaining amount information and the read average consumption current (step S44). Then, the notification part 150 notifies a user of the computed executable process amount of the process (step S45). In the portable equipment 100, when the notification device 18 is a device of outputting sound or voice, the notification part 150 may notify the user of the computed executable process amount computed by the notification device 18 by outputting it as sound or voice.

Additionally, in the portable equipment 100, if the notification device 18 is, for example, a device having a display function, the notification part 150 may cause the notification device to display as a message the executable process amount computed. Furthermore, in the portable equipment 100, if the notification device 180 is, for example, a buzzer, etc., the notification part 150 may notify the user of a reduction in the executable process amount by sounding a buzzer by the notification device 180.

Although the executable process amount is computed and notified upon receipt of the notification instruction in the process illustrated in FIG. 4, it is not limited to this process. The portable equipment 100 according to the present embodiment may periodically compute the executable process amount, and when the executable process amount is equal to or smaller than a predetermined amount, the notification part 150 may perform a notification.

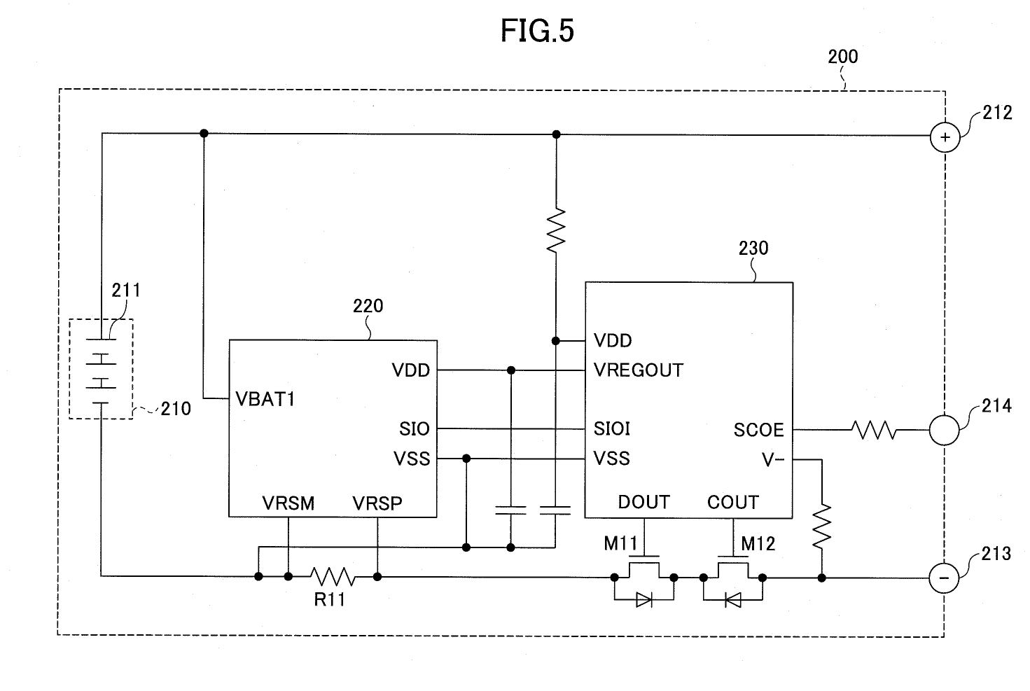

Here, a description will be given, with reference to the drawings, of the battery pack 200 built in the portable equipment 100. FIG. 5 is a circuit diagram of the battery pack mounted in the portable equipment.

The battery pack 200 has a battery unit 210 to which a plurality of secondary batteries 211 such as, for example, lithium ion batteries are connected. Although the battery unit 210 contains the plurality of secondary batteries 211 serially connected in the present embodiment, the structure of the battery unit 210 is not limited to this. The battery pack 200 has a monitor IC 220 and a protection IC 230 between the battery unit 210 and a positive terminal 212 and a negative terminal 213 for connecting to the portable equipment 100 to which the battery pack 200 is mounted.

The monitor IC 220 monitors the state of the battery unit 210, and acquires state information of the battery unit 210. Then, upon reception of a reference request of the state information from the portable equipment 100, the monitor IC 220 provides the acquired state information to the portable equipment 100. The monitor IC 220 has a power supply terminal VDD and a reference potential terminal VSS, a voltage detection terminal VBAT1, one set of current detection terminals VRSP and VRSM, and a communication terminal SIO. The monitor IC 220 receives a voltage regulated from a battery voltage in the protection IC 230 through the power supply terminal VDD. The reference potential terminal VSS is connected to a negative terminal of the battery unit 210.

The monitor IC 220 detects an output voltage of the battery unit 210 through the voltage detection terminal VBAT1 connected to a positive terminal of the battery unit 210. The current detection terminal VRSM is connected to a negative terminal of the secondary battery 211, and further connected to the current detection terminal VRSP through a resistor R11 outside the monitor IC 220.

The monitor IC 220 detects a current flowing in the external resistor R11, that is, a charge and discharge current of the battery unit 210 through the current detection terminals VRSP and VRSM. The communication terminal SIO is connected to the external terminal 214 used for communication with the portable equipment 100 through the protection IC 230. The monitor IC 220 of the present embodiment communicates with the portable equipment 100 through the communication terminal SIO and the protection IC 230. The detail of the monitor IC 220 will be explained later.

The protection IC 230 protects the battery pack 200 from being overcharge and overdischarge. The protection IC 230 has a terminal DOUT and a terminal COUT connected to gates of MOS transistors M11 and M12, respectively, which interrupts a charge and discharge of the battery pack 200. The protection IC 230 turns off the MOS transistor M11 using a DOUT output as a low level when overdischarge or overcurrent is detected, and turns off the MOS transistor M12 using a COUT output as a low level when overcharge is detected by an overcurrent detection circuit.

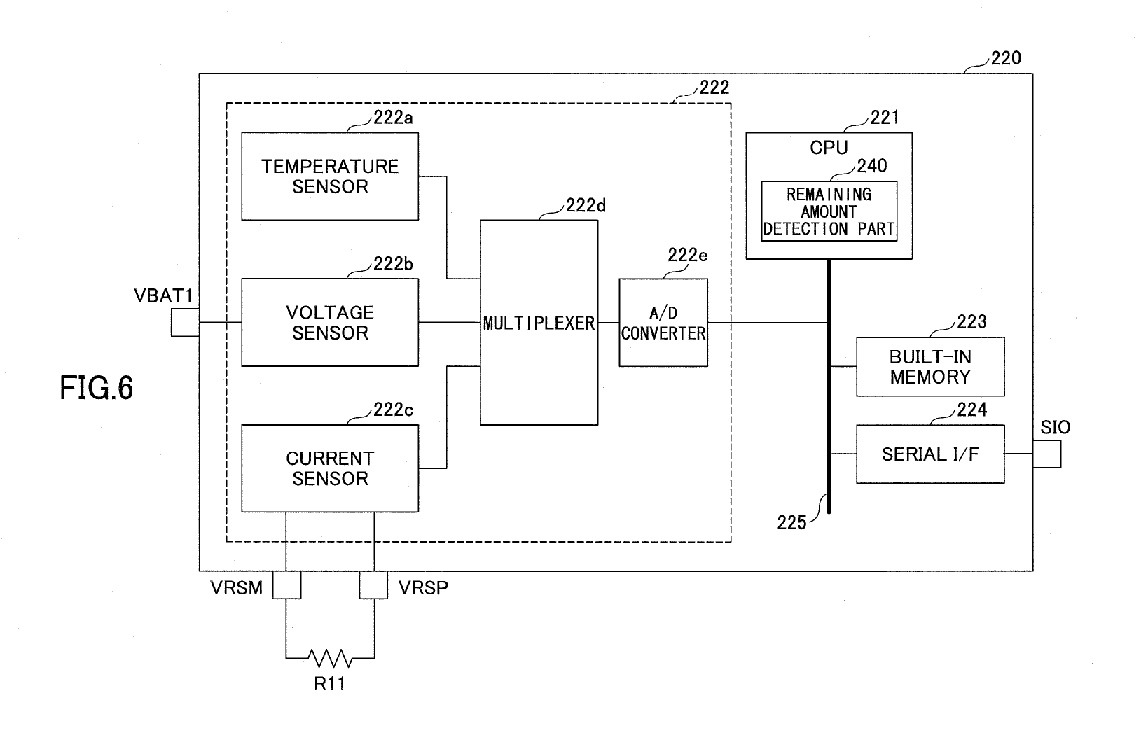

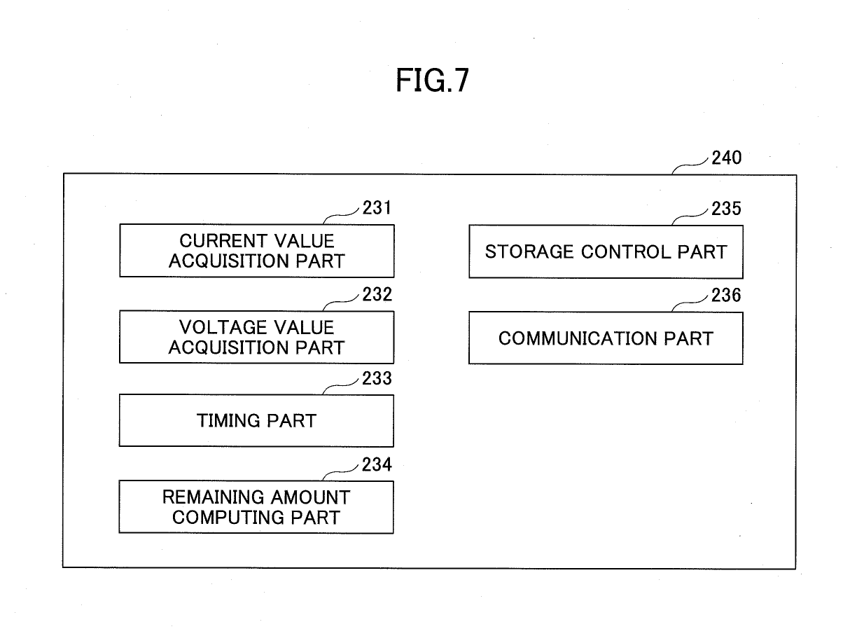

A description will be given below, with reference to FIG. 6 and FIG. 7, of the monitor IC 220 in detail. FIG. 6 is a block diagram illustrating a hardware structure of the monitor IC. In FIG. 6, the monitor IC 220 has a CPU (Central Processing Unit) 221, a sensor part 222, a built-in memory 223, and a serial interface (I/F) 224.

The CPU 221 controls each part of the monitor IC 220. The CPU 221 has a remaining amount detection part 240 which detects a remaining amount of the battery unit 210. The sensor part 222 detects a voltage, a current and a temperature of the battery unit 210. Information such as a program which the CPU executes to control each part of the monitor IC 220, a voltage, a current and a temperature of the battery unit 210 detected by the sensor part 22, and each parameter, etc., is stored in the built-in memory 223. The serial I/F 224 performs communication with the portable equipment through the communication terminal SIO. The CPU 221, the sensor part 222, the built-in memory 223, and the serial I/F 224 are connected by a bus 225 so that data and programs are exchanged therebetween.

The sensor part 222 contains a temperature sensor circuit 222a, a voltage sensor circuit 222b, a current sensor circuit 222c, a multiplexer 222d, and an analog-digital (A/D) conversion circuit 222e.

Temperature sensor circuit 222a detects the temperature of the battery unit 210. The voltage sensor circuit 222b detects an output voltage of the battery unit 210 through the voltage detection terminal VBAT1 connected to the battery unit 210. The current sensor circuit 222c detects a current flowing to the external resistor R11, i.e., a charge-and-discharge current of the battery unit 210, through the current detection terminals VRSP and VRSM. The output of each of the temperature sensor circuit 222a, the voltage sensor circuit 222b and the current sensor circuit 222c is connected to the multiplexer 222d, and is output as a single signal by the multiplexer 222d. The A/D conversion circuit 222e converts a signal output by the multiplexer 222d from an analog signal into a digital signal.

FIG. 7 is a block diagram illustrating a functional structure of the remaining amount detection part of the monitor IC. In the present embodiment, the functional structure of the remaining amount detection part 240 illustrated in FIG. 7 is realized by a specific program stored in the built-in memory 223 illustrated in FIG. 6.

The remaining amount detection part 240 has a current value acquisition part 231, a voltage value acquisition part 232, a timing part 233, a remaining amount computing part 234, a storage control part 235, and a communication part 236.

The current value acquisition part 231 acquires a current value detected by the current sensor circuit 222c. The voltage value acquisition part 232 acquires a voltage value detected by the voltage sensor circuit 222b. The timing part 233 counts time according to a timing function incorporated in the monitor IC 220.

The remaining amount computing part 234 computes an amount of battery power of the battery unit 210 according to the current value acquired by the current acquisition part 231 or the voltage value acquired by the voltage value acquisition part 232 and the timing function by the timing part 233.

The storage control part 235 causes the built-in memory 223 to store the state information such as, for example, the current value acquired by the current acquisition part 231, the voltage value acquired by the voltage value acquisition part 232, the remaining amount computed by the remaining amount computing part 234, etc. The communication part communicates with the portable equipment 100 into which the battery pack 200 is incorporated, and provides, for example, the remaining amount information indicating the remaining amount of the battery unit 210, etc., to the portable equipment 100.

The portable equipment 100 performs the above-mentioned notification using the remaining amount information of the battery unit 210 detected by the remaining amount detection part 240 in the monitor IC 210.

As explained above, in the present embodiment, a notification about the executable time of a process in the portable equipment can be sent to a user by the notification device 18 based on the battery remaining amount of the battery unit 210. Thus, according to the present embodiment, a user can be prompted to charge a secondary battery at an appropriate timing, and the portable equipment 100 is prevented from being in an unusable condition in an unintended sate during use of the portable equipment 100.

### Second Embodiment

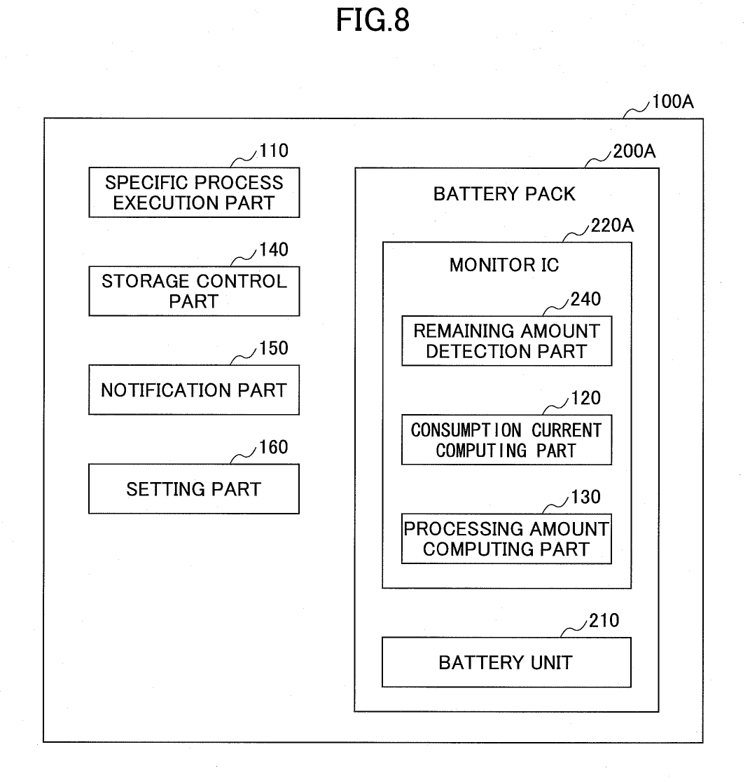

A description will be given, with reference to FIG. 8, of a second embodiment of the present invention. The portable equipment according to the second embodiment of the present invention differs from the portable equipment according to the first embodiment in that the consumption current computing part 120 and the processing amount computing part 130 are functions of a monitor IC of a battery pack. FIG. 8 is a block diagram illustrating a functional structure of the portable equipment according to the second embodiment. In FIG. 8, parts that are the same as the parts illustrated in FIG. 2 are given the same reference numerals, and descriptions thereof will be omitted.

The portable equipment 100A according to the second embodiment illustrated in FIG. 8 has a battery pack 200A. A monitor IC 220A provided in the battery pack 200A contains the consumption current computing part 120 and the processing amount computing part 130. In the monitor IC 220A, the consumption current computing part 120 computes an average value of the consumption current during execution of a process of the portable equipment based on a battery remaining amount of the battery unit 210 detected by the remaining amount detection part 240. Accordingly, the present embodiment can provide an effect the same as the first embodiment.

### Third Embodiment

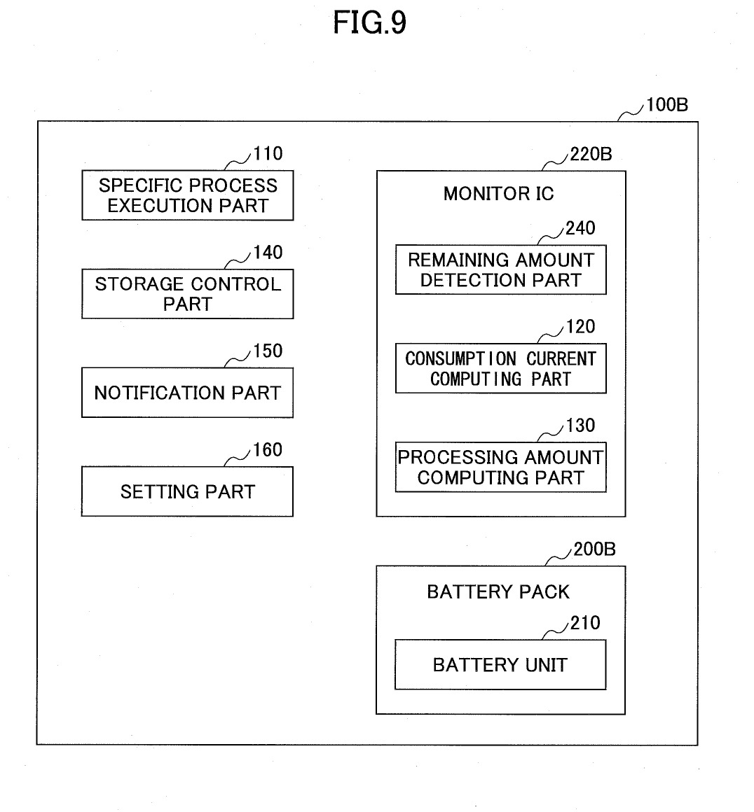

A description will be given, with reference to FIG. 9, of a third embodiment of the present invention. The portable equipment according to the third embodiment of the present invention differs from the second embodiment in that the monitor IC is provided outside the battery pack 200. FIG. 9 is a block diagram illustrating a functional structure of the portable equipment according to the third embodiment. In FIG. 9, parts that are the same as the parts illustrated in FIG. 2 are given the same reference numerals, and descriptions thereof will be omitted.

The battery pack 200B mounted to the portable equipment 100B according to the third embodiment has only the battery unit 210. The monitor IC 220B is provided not inside the battery pack 200B but outside the battery pack 200B. The monitor IC 220B contains the remaining amount detection part 240, the consumption current computing part 120, and the processing amount computing part 130.

The remaining amount detection part 240 of the monitor IC 220B according to the present embodiment detects a battery remaining amount of the battery unit 210 provided in the battery pack 200B based on a current flowing in, for example, a ground line or the like of a body of the portable equipment 100B. Because the consumption current computing part 120 and the processing amount computing part 130 have been explained in the first and second embodiments, descriptions thereof will be omitted. As mentioned above, the present embodiment can provide an effect the same as the first embodiment.

In addition, different from the battery pack 200 of the first embodiment explained with reference to FIG. 5, the battery pack 200B according to the present embodiment does not have the monitor IC 220 and has only the protection IC 230.

### Fourth Embodiment

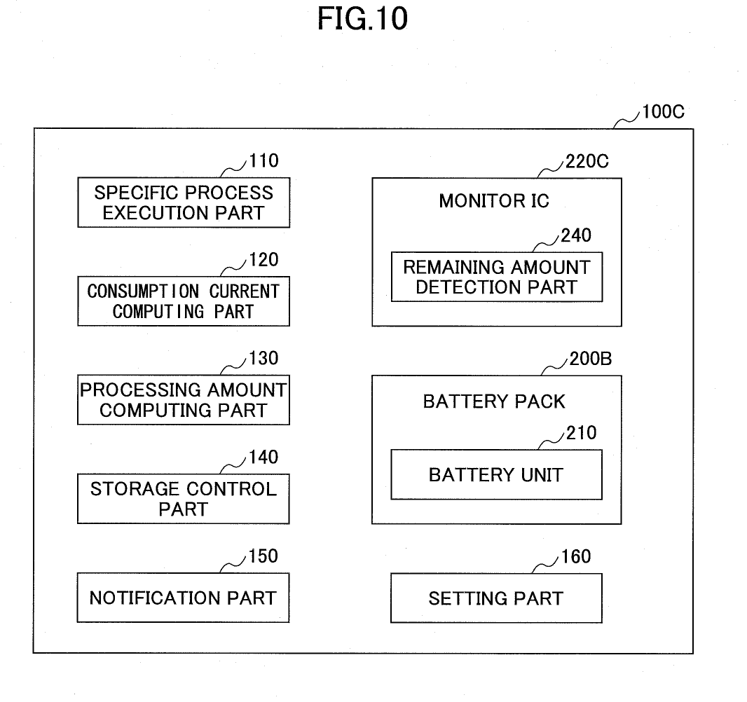

A description will be given, with reference to FIG. 10, of a fourth embodiment of the present invention. The portable equipment according to the fourth embodiment of the present invention differs from the second embodiment in that the consumption current computing part 120 and the processing amount computing part 130 are provided outside the monitor IC. FIG. 10 is a block diagram illustrating a functional structure of the portable equipment according to the fourth embodiment. In FIG. 10, parts that are the same as the parts illustrated in FIG. 9 are given the same reference numerals, and descriptions thereof will be omitted.

The battery pack 200B is mounted in the portable equipment 100C illustrated in FIG. 10. The monitor IC 220C according to the present embodiment is provided not inside the battery pack 200B but outside the battery pack 200B.

The monitor IC 220C has the remaining amount detection part 240. The remaining amount detection part 240 of the monitor IC 220C detects a battery remaining amount of the battery unit 210 provided in the battery pack 200B based on a current flowing in, for example, a ground line or the like of a body of the portable equipment 100C. Because the consumption current computing part 120 and the processing amount computing part 130 have been explained in the first and second embodiments, descriptions thereof will be omitted. As mentioned above, the present embodiment can provide an effect the same as the first embodiment.

### Fifth Embodiment

A description will be given of a fifth embodiment of the present invention. The fifth embodiment of the present invention is a form in which the first through fourth embodiments are applied to a portable printing device.

In the portable equipment according to the present embodiment (hereinafter, referred to as a portable printing device), the specific process execution part 110 executes a print process. Moreover, in the portable printing device according to the present embodiment, the input device 110 is a device for inputting, for example, print data. The device for inputting print data may be a keyboard such as, for example, ten key, etc. The output device 12 may includes a plotter for printing print data and a control means for controlling the plotter.

The notification device according to the present embodiment may be, for example, a sound/voice output device, and an executable process amount computed by the processing amount computing part 130 may be notified by sound or voice. Alternatively, the notification device may include a display device, which displays an executable process amount computed by the processing amount computing part 130.

The portable printing device according to the present embodiment may be used in a meter check of, for example, water service, electricity supply service, etc. Moreover, the portable printing device according to the present embodiment may have a structure simpler than the hardware structure illustrated in FIG. 1. For example, the portable printing device according to the present embodiment does not have the drive device 13 and the auxiliary storage device 14, and may have a structure which does not read the recording medium 19.

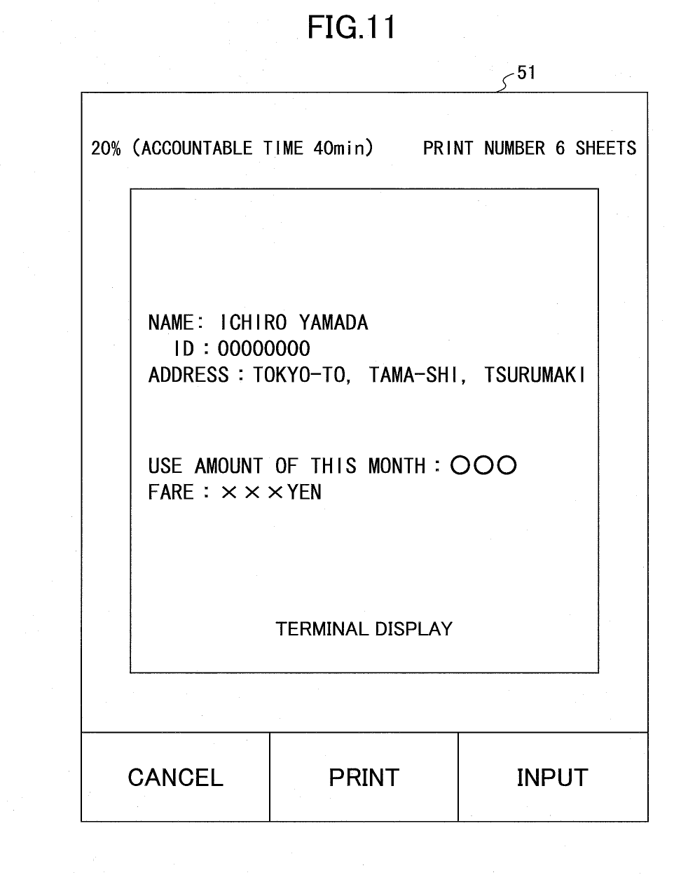

FIG. 11 is a view illustrating a screen to notify of an executable process amount in the portable printing device according to the fifth embodiment. In the screen 51 illustrated in FIG. 11, a number of printable sheets is displayed as an executable process amount. Moreover, in the screen 51, a usable time of the portable printing device is also displayed.

In a case of a portable printing device having no display function, a host computer may be caused to display the screen 51 through the communication device 17.

A description will be given below of a process of computing an executable process amount in the portable printing device according to the present embodiment.

In the portable printing device according to the present embodiment, the processing amount computing part stores a consumption current when outputting, for example, one sheet of print paper. Then, the processing amount computing part 130 computes a number of printable sheet as the executable process amount based on the battery remaining amount detected by the remaining amount detection part 240 and the consumption current for each print paper. Alternatively, the processing amount computing part 130 may store the consumption current for each number of printed characters in order to compute an executable process amount based on the consumption current for each number of characters and the battery remaining amount. In this case, the executable process amount may be displayed as a number of printable characters. Moreover, the consumption current may be stored for each predetermined number of print characters to compute the executable process amount based on the consumption current.

### Sixth Embodiment

A description will be given of a sixth embodiment. The sixth embodiment of the present embodiment is a form in which the first through fourth embodiments are applied to a digital camera.

In the portable equipment according to the present embodiment (hereinafter, referred to as a digital camera), the specific process execution part 110 executes a photographing process of an image. Moreover, in the digital camera according to the present embodiment, the input device 110 is an operation device for operating the digital camera. The output device 12 is a device for outputting the photographed picture to, for example, a recording medium or an external device.

The notification device 18 may be, for example, a sound/voice output device, and an executable process amount computed by the processing amount computing part 130 may be notified by sound or voice. Alternatively, the notification device 18 may include a display device, which displays an executable process amount computed by the processing amount computing part 130.

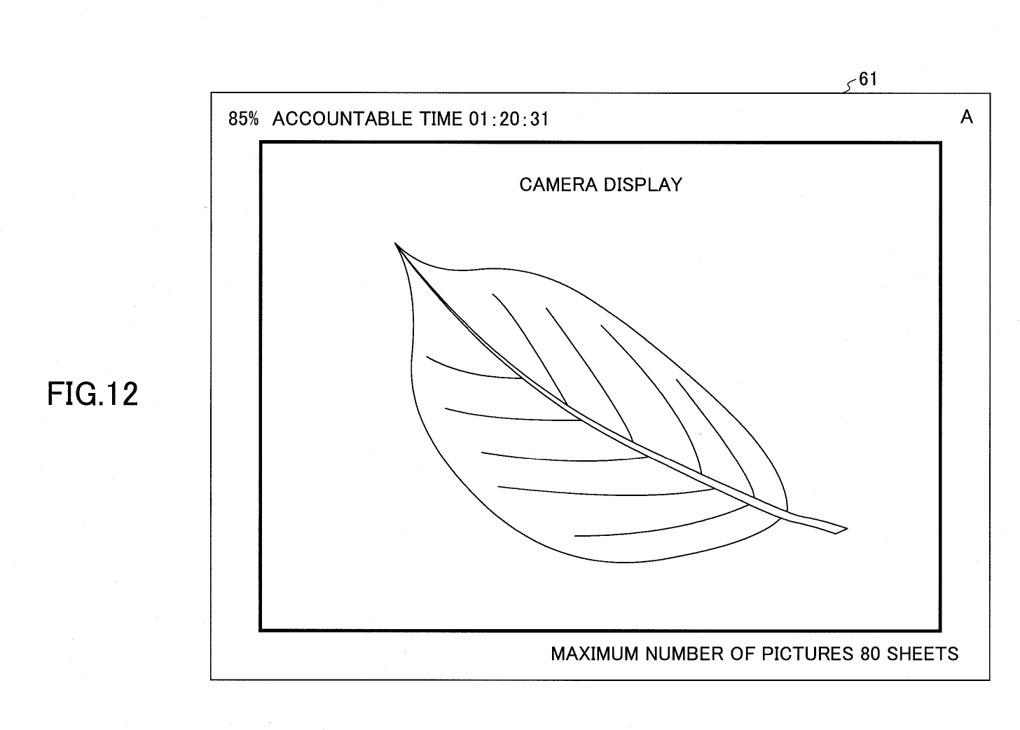

FIG. 12 is a view illustrating a screen to notify of an executable process amount in the sixth embodiment. In the screen 61 illustrated in FIG. 12, a number of pictures that can be taken is displayed as an executable process amount. Moreover, in the screen 61, an available time of the digital camera is also displayed.

A description will be given below of a process of computing an executable process amount in the digital camera according to the present embodiment.

In the digital camera according to the present embodiment, the processing amount computing part 130 stores a consumption current when photographing, for example, one sheet of picture. Then, the processing amount computing part 130 computes a number of sheets of picture that can be taken as an executable process amount based on the battery remaining amount detected by the remaining amount detection part 240 and the consumption current for each shoot.

Additionally, in the digital camera according to the present embodiment, a number of sheets of picture that can be taken may be computed in response to, for example, a selected picture mode. For example, in a case where a flash mode is selected in which a flash light is used when shooting, the processing amount computing part 130 computes a number of sheets of picture that can be taken in the flash mode, and notifies it.

In this case, the processing amount computing part 130 stores the consumption current when taking a picture in the flash mode. Then, if the flash mode is selected when an instruction of notification for a number of sheets of picture that can be taken is received, the processing amount computing part 130 computes the number of sheets of picture based on the consumption current in the flash mode. Alternatively, the processing amount computing part 130 may computes a usable time of the digital camera in the flash mode.

In the present embodiment, according to the structure mentioned above, a notification of a number of sheets of picture that can be taken can be made based on the battery remaining amount of the battery unit 210, and it can prompt a user to charge an appropriate timing as compared to a conventional digital camera, which notifies only a number of sheets of picture that can be taken in response to an amount of space of a recording medium (memory).

If the digital camera according to the present embodiment is capable of taking a motion picture, an average value of consumption current during taking a motion picture is computed by the consumption current computing part 120 in order to compute a photographable time based on the average value computed by the processing amount computing part 130.

### Seventh Embodiment

A description will be given below of a seventh embodiment. The seventh embodiment of the present invention is a form in which the first through fourth embodiments are applied to a DVD (Digital Versatile Disc) player 100D.

In the portable equipment according to the present embodiment (hereinafter, referred to as a DVD player), the specific process execution part 110 executes a process of reproducing a motion picture or a static picture recorded on a DVD, which is a recording medium, set in the DVD player 100D. Additionally, in the DVD player 100D, the input device 11 is, for example, an operation device for operating the digital camera. The output device 12 is, for example, a display device for displaying a reproduced image.

The notification device 18 according to the present embodiment may be, for example, a sound/voice output device, which may notify of an executable process amount computed by the processing amount computing part 130 by sound or voice. Alternatively, the notification device 18 may be a display device, which may be caused to display an executable process amount computed by the processing amount computing part 130.

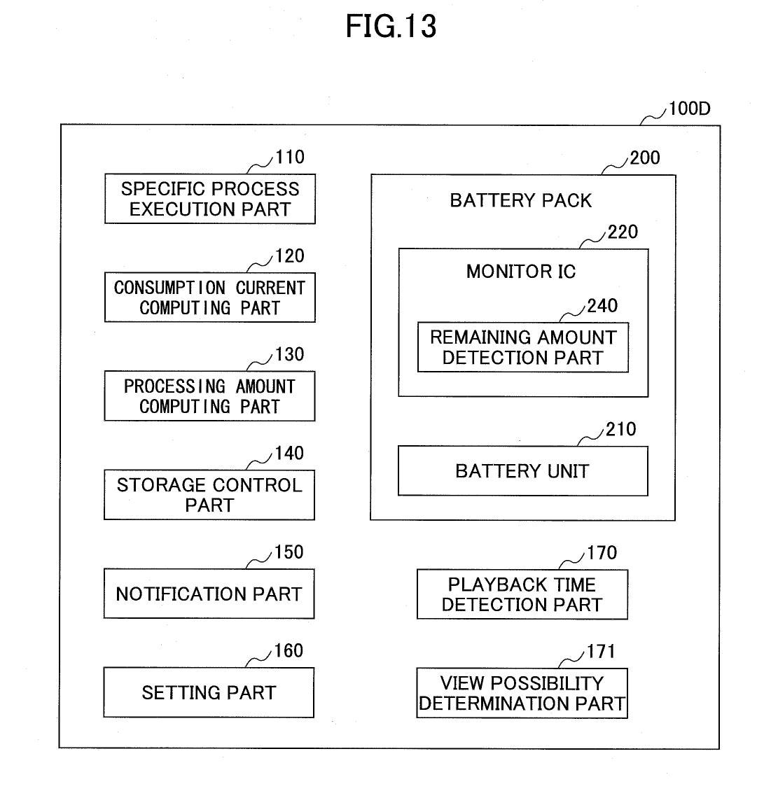

FIG. 13 is a block diagram illustrating a functional structure of a DVD player according to the seventh embodiment. The DVD player 100D according to the present embodiment has a playback time detection part 170 and a view possibility determination part 171 in addition to each part of the portable equipment 100 explained in the first embodiment.

In the DVD player 100D, the consumption current computing part 120 computes an average value of a consumption current of the DVD player 100D during playback of a motion picture recorded on a recording medium set in the DVD player. The processing amount computing part 130 computes a viewable time of the DVD as an executable process amount based on the computed average value.

The notification part 150 according to the present embodiment causes the output device 12 (display device) to display the viewable time computed by the processing amount computing part 130. Additionally, the notification part 150 may notify of the viewable time by sound or voice by the notification device 18.

Moreover, the DVD player 100D according to the present embodiment can determine, when, for example, a DVD is set to the DVD player 100D, whether or not the DVD is continuously viewable and, can notify of it.

When a DVD is set to the DVD player 100D according to the present embodiment, the playback time detection part 170 detects a playback time of the DVD set in the DVD player. Then, the processing amount computing part 130 computes a viewable time. Then, the view possibility determination part 171 determines whether or not the set DVD can be continuously played by referring to the playback time and the viewable time.

The view possibility determination part 171 determines, if the viewable time is longer than the reproduction time, that it is possible to view continuously, and determines, if the viewable time is shorter than the reproduction time, that it is impossible to view continuously. If it is determined that it is impossible to view continuously, the view possibility determination part 171 according to the present embodiment may cause the display device to display such a condition by the notification part 150.

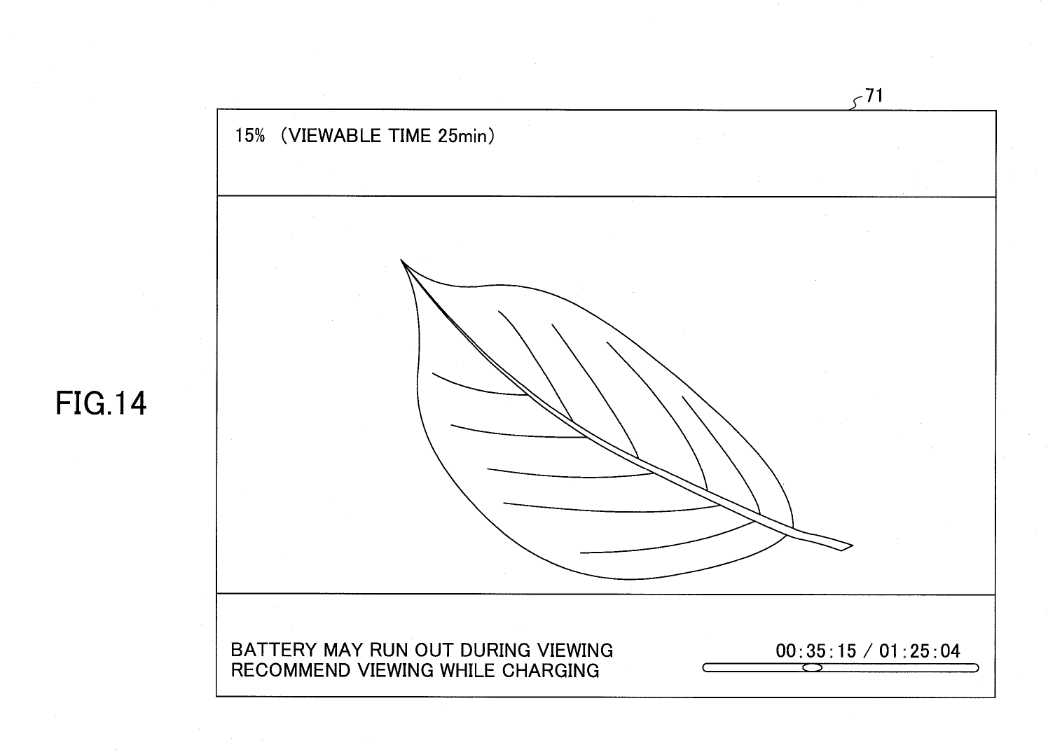

FIG. 14 is a view illustrating a screen to notify of an executable process amount in the seventh embodiment. In the screen 71 illustrated in FIG. 14, a viewable time is displayed as an executable process amount. Additionally, in the screen 71, a usable time of the digital camera is also displayed. Further, in the screen 71, a message to prompt a charge when a viewable time becomes short is displayed.

Although the example in which the first embodiment is applied to the DVD player 100D has been explained, the second embodiment to fourth embodiment can also be applied to the DVD player 100D.

### Eighth Embodiment

A description will be given below of an eighth embodiment of the present invention. The eighth embodiment of the present invention is a form in which the first through fourth embodiments are applied to a music data playback device.

In the portable equipment according to the present embodiment (hereinafter, referred to as a music data playback device), the specific process execution part 110 executes, for example, a playback process of music data. Additionally, in the music data playback device according to the present embodiment, the input device 11 may be, for example, an operation device for operating the music data playback device.

The output device 12 according to the present embodiment is, for example, a device for outputting music data that is reproduced. In the present embodiment, the music data may be recorded, for example, on the recording medium 19, and may be read by the drive device 13 and recorded in the auxiliary storage device 14.

The notification device 18 according to the present embodiment may be, for example, a sound/voice output device, and may notify of an executable process amount computed by the processing amount computing part 130 by sound or voice. Alternatively, the notification device 18 may be a display device, which may be caused to display an executable process amount computed by the processing amount computing part 130.

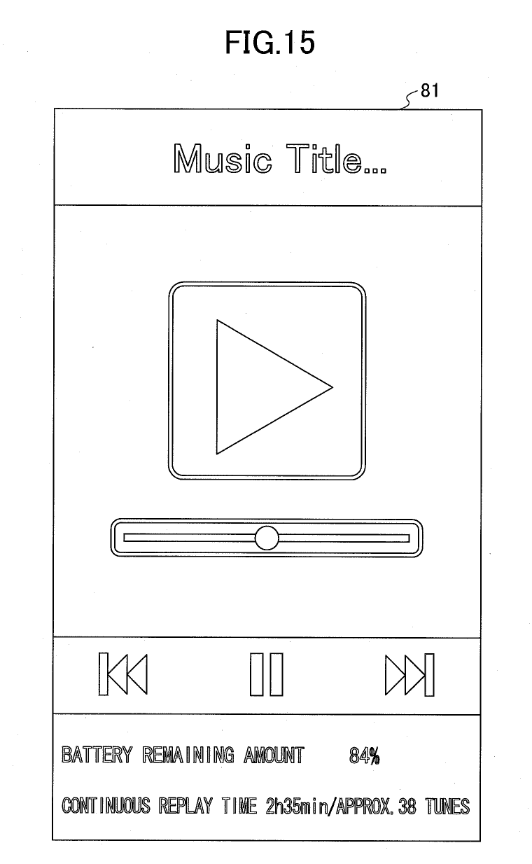

FIG. 15 is a view illustrating a screen to notify an executable process amount in the eighth embodiment. In the screen 81 illustrated in FIG. 15, a number of tunes is displayed as an executable process amount. Additionally, in the screen 81, a usable time of the music data playback device is also displayed.

A description will be given below of a computation of an executable process amount in the music data playback device according to the present embodiment.

In the present embodiment, the consumption current computing part 120 computes an average value of a consumption current during a reproduction operation of music data. In the present embodiment, the consumption current computing part 120 computes an average value of a time spent on reproducing music data corresponding to one tune. The consumption current computing part 120 computes a consumption current for reproducing each tune based on the average value of the consumption current at the time of reproducing music data and the average value of a playback time of one tune. The processing amount computing part 130 computes a number of tunes that can be playback as an executable process amount based on the battery remaining amount of the battery unit 210 and the consumption current for reproducing each tune.

### Ninth Embodiment

A description will be given of a ninth embodiment of the present invention. The ninth embodiment of the present invention is a form in which the first through fourth embodiments are applied to a portable navigation device.

In the portable equipment according to the present embodiment (hereinafter, referred to as a portable navigation device), the specific process execution part 110 performs, for example, a navigation process. The input device 11 may be an operation device for operating, for example, the portable navigation device. The output device 12 is a device for outputting (displaying) position information acquired by, for example, a navigation process, and is a display device.

The notification device 18 according to the present embodiment is, for example, a sound/voice output device, and may notify of an executable process amount computed by the processing amount computing part 130 by sound or voice. Alternatively, the notification device 18 may be a display device, which may display an executable process amount computed by the processing amount computing part 130.

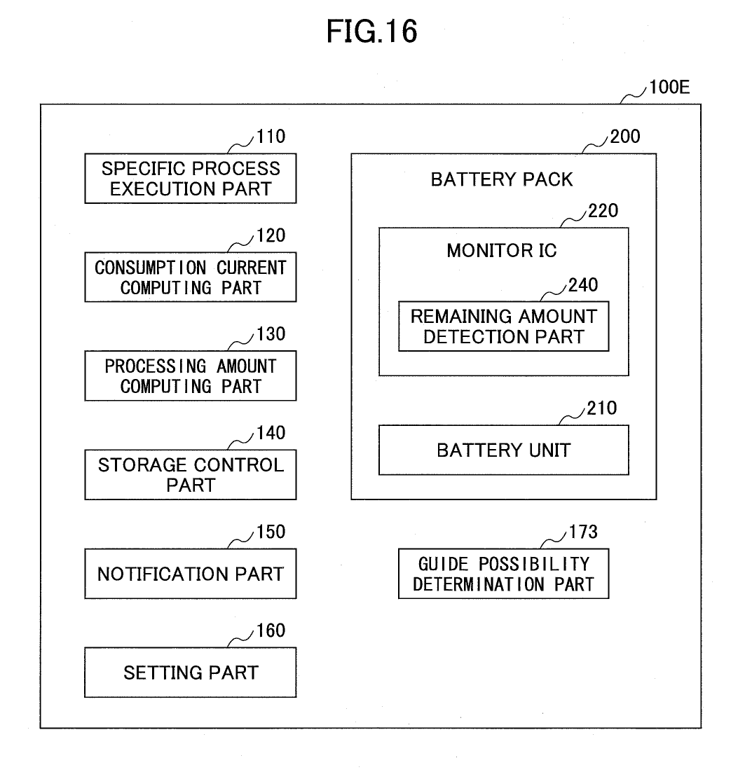

FIG. 16 is a block diagram illustrating a functional structure of the portable navigation device according to the ninth embodiment. In addition to each part of the portable equipment 100 explained in the first embodiment, the portable navigation device 100E according to the present embodiment has a guide possibility determination part 173.

In the portable navigation device 100E according to the present embodiment, the consumption current computing part 120 computes an average value of the consumption current during execution of the navigation process. The processing amount computing part 130 computes a usable time of the portable navigation device 100E as an executable process amount based on the computed average value.

The notification part 150 according to the present embodiment causes the output device 12 (display device) to display the usable time computed by the processing amount computing part 130. Alternatively, the notification part 150 may notify of the usable time by sound or voice through the notification device 18.

The guide possibility determination part 173 according to the present embodiment determines whether a guide according to the navigation process can be performed until the portable navigation device 100E arrives at a destination. If a destination is set in the portable navigation device 100E, the guide possibility determination part 173 causes the processing amount computing part 130 to compute a usable time. The guide possibility determination part 173 acquires position information of the destination, and computes a required time to the destination. Then, the guide possibility determination part 173 compares the required time to the destination with the usable time, and determines that a guide can be done if the required time is shorter than the usable time. The guide possibility determination part 173 determines that a guide cannot be done if the required time is longer than the usable time. The guide possibility determination part 173 causes the notification part 150 to notify the usable time and a message to prompt a charge.

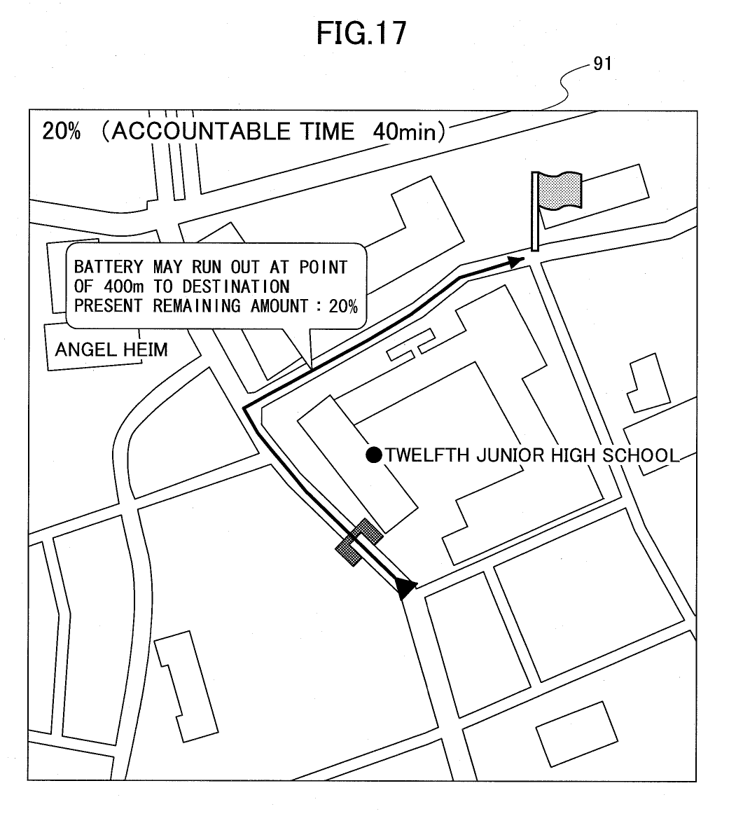

FIG. 17 is a view illustrating a screen to notify of an executable process amount in the ninth embodiment. In the screen 91 illustrated in FIG. 17, the usable time as an executable amount and the message to prompt a charge are displayed.

Although the example in which the portable equipment of the first embodiment is applied to the portable navigation device 100E has been explained in the present embodiment, the second through fourth embodiments can also be applied to the portable navigation device 100E.

### Tenth Embodiment

A description will be given of a tenth embodiment. The tenth embodiment of the present invention is a form in which the first through fourth embodiments are applied to a controller of a game machine.

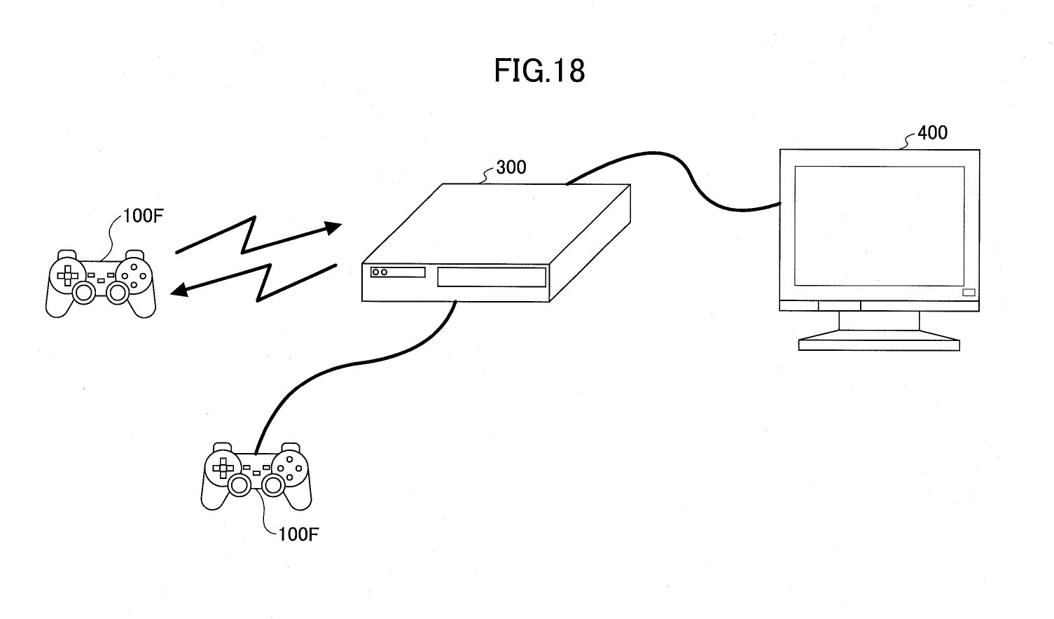

FIG. 18 is a view illustrating a game machine having a controller according to the tenth embodiment.

The controller 100F according to the present embodiment communicates with, for example, a main body 300 of the game machine and performs transmission and reception of information to progress a game. The main body 300 is connected to a display 400 to cause the display 400 to display a play screen, etc., of the game. In the present embodiment, the main body 300 and the display 400 are wire-connected.

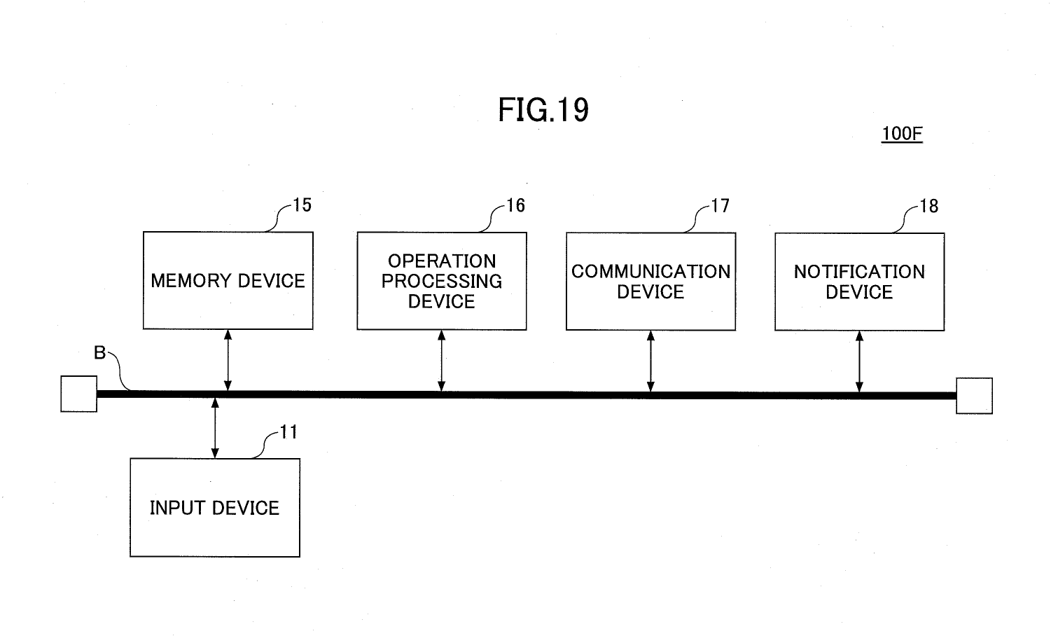

FIG. 19 is a block diagram illustrating a hardware structure of the controller according to the tenth embodiment. The controller 100F according to the present embodiment has the input device 11, the memory device 15, the operation processing device 16, the communication device 17 and the notification device 18 of the portable equipment 100 according to the first embodiment. In the present embodiment, the input device 11 is, for example, an operation device to input operation information. The operation information input by the input device 11 is transmitted to the main body 300 by the communication device 17. Moreover, the information transmitted from the main body 300 is received by the communication device 17. In the present embodiment, the notification device 18 may be, for example, a speaker, etc.

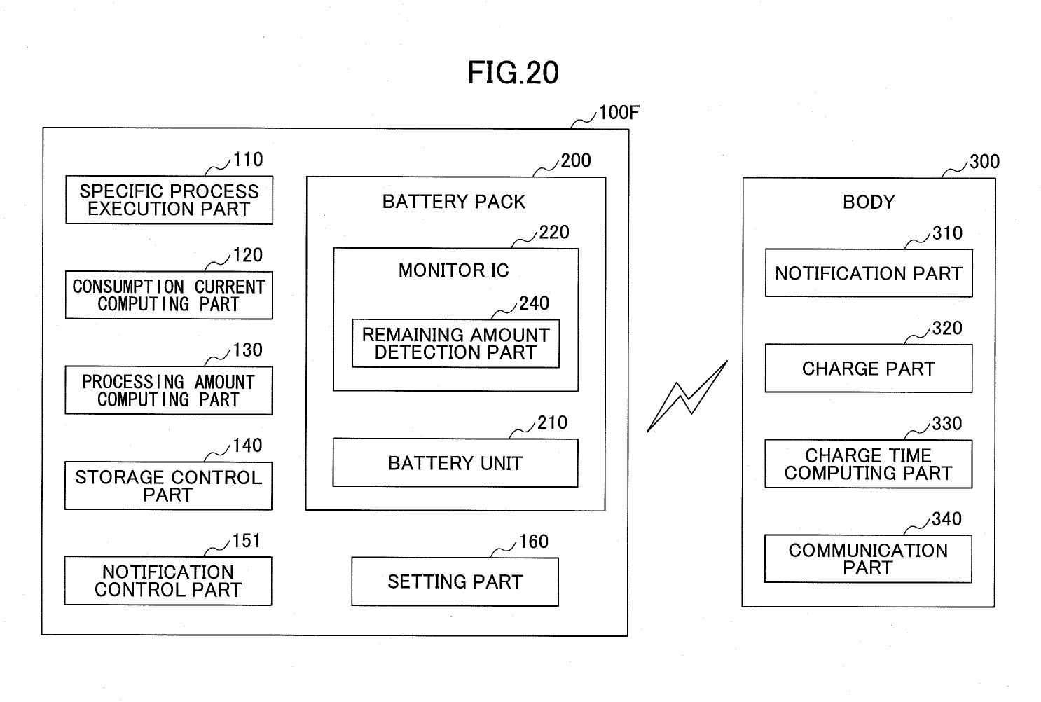

FIG. 20 is a block diagram illustrating functions of the controller and the main body according to the tenth embodiment. The controller 100F according to the present embodiment has the specific process execution part 110, the consumption current computing part 120, the processing amount computing part 130, the storage control part 140, the setting part 160 and the battery pack 200 of the portable equipment 100 according to the first embodiment. Moreover, the controller 100F according to the present embodiment has a notification control part 151.

Also in the controller 100F according to the present embodiment, the specific process execution part 110 performs transmission and reception process of the operation information to progress a game. The consumption current computing part 120 computes an average value of a consumption current during transmission and reception of the operation information. The processing amount computing part 130 computes a transmissible and receivable time of the operation information as an executable process amount based on the average value of the consumption current. The notification control part 151 notifies a user of the transmissible and receivable time computed by the communication device 17. Specifically, the notification control part 151 displays the computed transmissible and receivable time on the display 400 through the main body 300.

The main body 300 is a computer having an operation processing device and a memory device, and has a notification part 310, a charge part 320, a charge time computing part 330 and a communication part 340.

The notification part 310 displays the transmissible and receivable time from the notification control part 151 of the controller 100F on the display 400. The notification part 310 according to the present embodiment may cause the display 400 to display the transmissible and receivable time and the message to prompt a charge.

The charge part 320 has a charge circuit for charging the battery unit 210 of the controller 100F. The charge time computing part 330 notifies a user of a charge required time computed by the charge time computing part 330 on the display 400 when a charge of the battery unit 210 by the charge part 320 is started. Additionally, the controller 100F of the present embodiment may notify the user of the transmissible and receivable time by sound or voice by the notification device (for example, a speaker).

According to the present embodiment, for example, a user is caused to determine necessity of charge before starting a game by notifying the user of the transmissible and receivable time of the controller 100F before starting the game, in order to prompt a user to perform a charge at an appropriate timing. Thereby, battery exhaustion can be prevented beforehand under a condition in which it is difficult to interrupt a play such as, for example, in a fighting game.

Although the portable equipment according to the first embodiment is applied to the controller 100F in the present embodiment, the second thorough fourth embodiments can also be applied to the controller 100F.

Moreover, in the present embodiment, the consumption current computing part 120 and the processing amount computing part 130 may be provided, for example, in the main body 300. In this case, the controller 100F transmits the battery remaining amount detected by the remaining amount detection part 240 to the main body 300. The main part 300 can compute the transmissible and receivable time based on the battery remaining amount.

### Eleventh Embodiment

A description will be given below of an eleventh embodiment of the present invention. The eleventh embodiment of the present invention is a form in which the first through fourth embodiments are applied to a sound/voice output device.

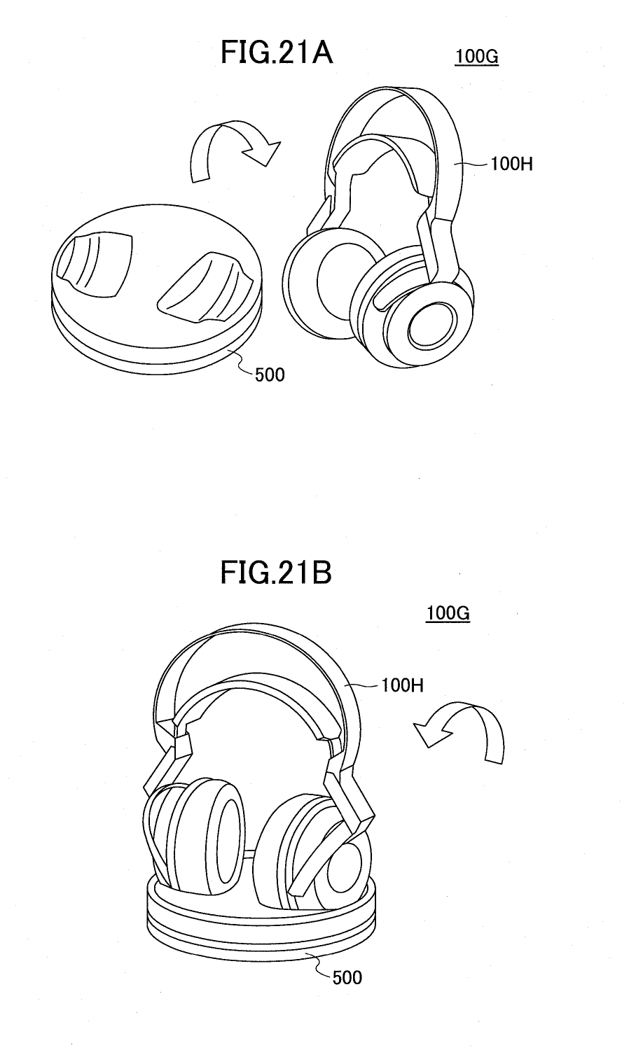

FIGS. 21A and 21B are views illustrating a sound/voice data output device according to the eleventh embodiment. The sound/voice data output device 100G according to the present embodiment has a reception device 100H and a transmission device 500. The transmission device 500 transmits sound/voice data to the reception device 100H.

The reception device 100H outputs the received sound/voice data. The sound/voice data is stored in the transmission device 500. The reception device 100H is driven by a secondary battery, and performs wireless communication with the transmission device 500.

In the sound/voice data output device 100G according to the present embodiment, the reception device 100H is driven by the secondary battery in the reception device 100H when it is separated from the transmission device 500 as illustrated in FIG. 21A. The secondary battery of the reception device 100H is charged by the transmission device 500 if it is connected and set to the transmission device 500 as illustrated in FIG. 21B.

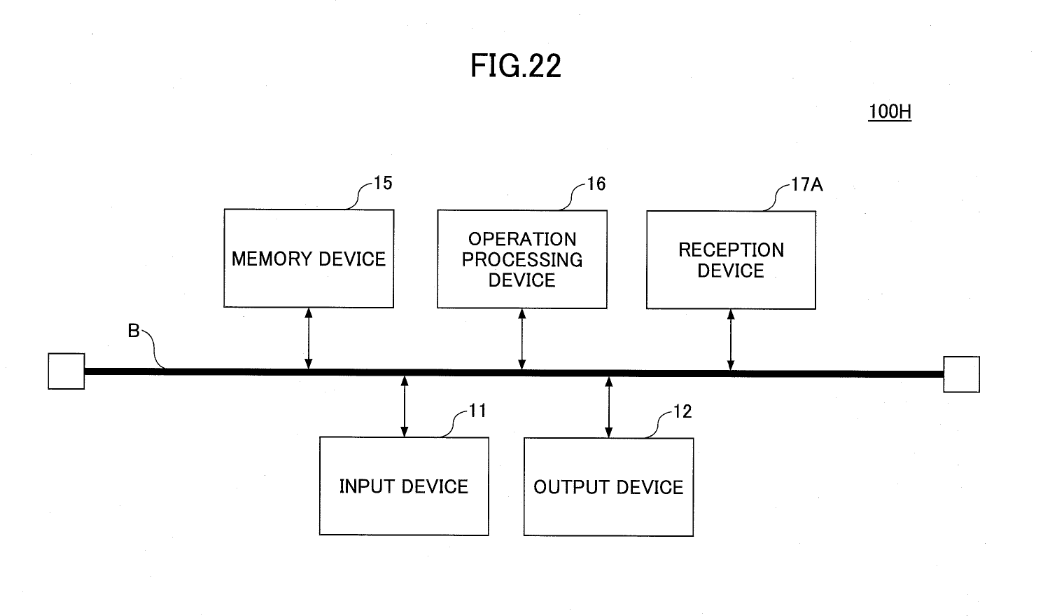

FIG. 22 is a block diagram illustrating a hardware structure of the reception device according to the eleventh embodiment. The reception device 100H of the present embodiment has the input device 11, the output device 12, the memory device 15, the operation processing device 16 and a reception device 17A. In the reception device 100H of the present embodiment, the input device 11 is provided in order to operate, for example, the reception device 100H. The reception device 100H according to the present embodiment is provided with an operation member, etc., to adjust a volume when outputting, for example, sound/voice data, which corresponds to the input device 11.

In the reception device 100H according to the present embodiment, the output device 12 is provided to output sound/voice data. The communication device 17 performs wireless communication with the transmission device 500.

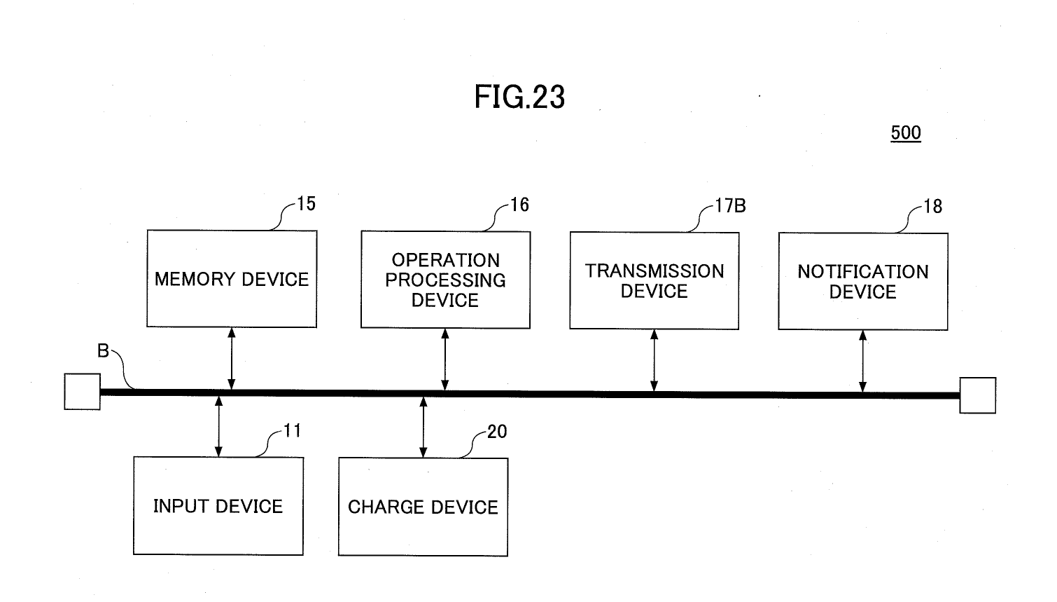

FIG. 23 is a block diagram illustrating a hardware structure of the transmission device according to the eleventh embodiment. The transmission device 500 according to the present embodiment has the input device 11, the memory device 15, the operation processing device 16, transmission device 17B, the notification device 18 and the charge device 20. In the transmission device 500 according to the present embodiment, the input device 11 is provided to input sound/voice data. The transmission device 17B is provided to transmit input sound/voice data to the reception device 100H.

The notification device 18 is provided to notify of an output capable time of the reception device 100H. The notification device 18 may be, for example, a device to send a notification by sound or voice. Alternatively, the notification device 18 may be a device which sends a notification by causing the output possible time to be displayed. The charge apparatus 20 is provided to charge the reception device 100H. The charge device 20 starts to charge the secondary battery if the reception device 100H is located at a predetermined position of the transmission device 500.

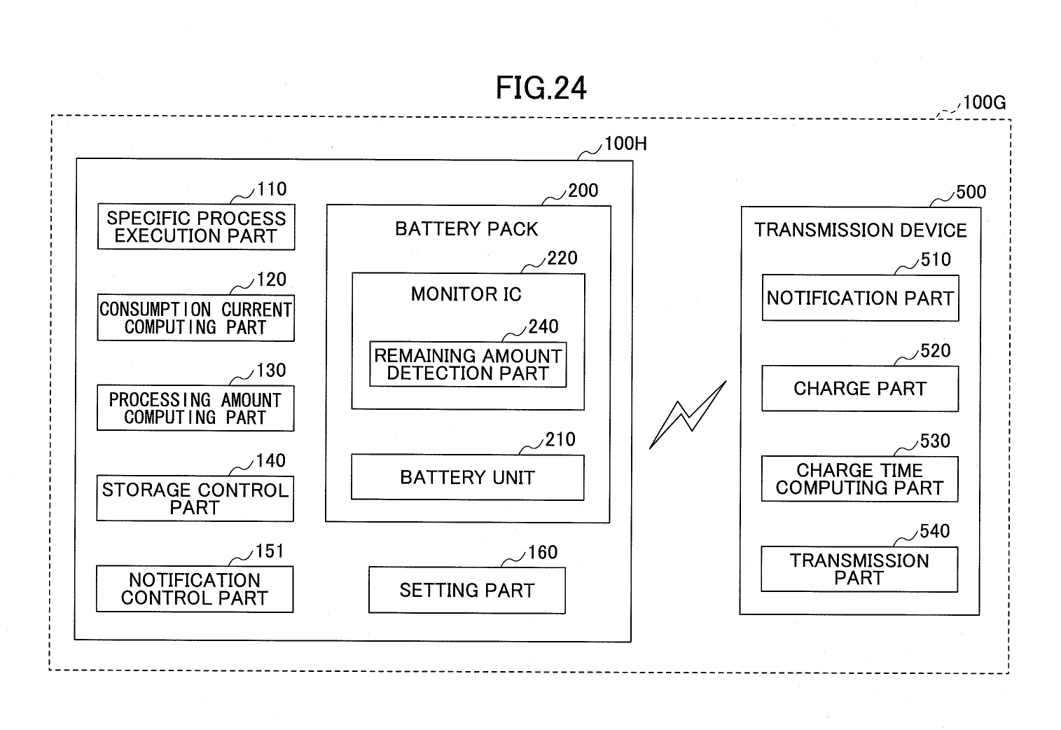

FIG. 24 is a block diagram illustrating functions of the sound/voice data output device of the eleventh embodiment. The reception device 100H of the sound/voice data output device 100G according to the present embodiment has the same functional structure as the controller 100F of the tenth embodiment.

In the reception device 100H according to the present embodiment, the specific process execution part 110 performs a process of receiving and outputting sound/voice data. The consumption current computing part 120 computes an average value of a consumption current during output of the sound/voice data. The processing amount computing part 130 computes an output possible time of sound/voice data as an executable process amount based on the battery remaining amount of the battery unit 210 and the average value of the consumption current. The notification control part 151 causes the transmission device 500 to notify of the output possible time computed by the processing amount computing part 130.

The transmission device 500 according to the present embodiment has a notification part 510, a charge part 520, a charge time computing part 530 and a transmission part 540. The notification part 510 notifies a user of an output possible time by the notification device 18 upon reception of an instruction from the communication control part 151. The notification part 510 according to the present embodiment can notify a user of also the charge required time mentioned later.

The charge part 520 starts a charge of the battery unit 210 by the charge device 20 if it detects that the reception device 100H is connected. The charge time computing part 530 computes the charge required time of the battery unit 210. The transmission part 540 transmits the sound/voice data stored in the memory device 15 to the reception device 100H.

A description will be given below of an operation of the sound/voice data output device 100G according to the present embodiment. The transmission device 500 according to the present embodiment detects, if the reception device is separated from the transmission device 500, that the connection with the reception device 100H is interrupted. If the connection is interrupted, the transmission apparatus 500 notifies of the output possible time of the sound/voice data received from the notification control part 151 of the reception device 100H through the notification device 18 immediately before it by the notification part 510.

The transmission device 500 detects connection with reception device 100H if the reception device 100H is arranged on the transmission device 500. The transmission device 500 starts a charge of the battery unit 210 by the charge part 520, if it is connected to the reception device 100H. Moreover, the charge time computing part 530 computes a charge required time based on a battery remaining amount of the battery unit 210. The notification part 510 notifies a user of the computed charge required time.

In the present embodiment, according to the above-mentioned structure, a user can be caused to determine necessity of charge of the reception device 100H before using the reception device 100H, which can prompt the user to charge at an appropriate timing. Additionally, a notification is sent to the user about when the reception device 100H becomes usable next time.

In addition, although reception device 100H of the present embodiment is not provided with a notification means, it is not limited to this. The reception device 100H according to the present embodiment may have a notification means. The notification means provided in the reception device 100H may be included in, for example, the output device 12, and may notify of the output possible time by sound or voice. Additionally, the notification means provided in the reception device 100H may be, for example, a lighting means such as, for example, an LED (Light Emitting Diode). In this case, for example, the output possible time may be notified by lighting when the output possible time becomes shorter than a predetermined time.

If the reception device 100H of the present embodiment has a notification means, the present embodiment can be realized by the same functional structure as the portable equipments according first through fourth embodiments.

In the sound/voice data output device 100G of the present embodiment, the processing amount computing part 130 may be provided in the transmission device 500.

In this case, the transmission device 500 computes the output possible time based on a battery remaining amount of the battery unit 210 immediately before the time when the connection with the reception device 100H is interrupted, and notifies it by the notification part 520.

Additionally, in the sound/voice data output device 100G of the present embodiment, the consumption current computing part 120 and the processing amount computing part 130 may be provided in the transmission device 500. In this case, the consumption current computing part 120 computes the output possible time based on a battery remaining amount when the connection between the transmission device 500 and the reception device 100H is cut off, a battery remaining amount when the connection between the transmission device 500 and the reception device 100H is detected, and a time period during which the connection between the transmission device 500 and the reception device 100H is cut off. The processing amount computing part 130 computes the output possible time based on the average value of the consumption current and the battery remaining amount.

The present invention is not limited to the specifically disclosed embodiments, and variations and modifications may be made without departing from the scope of the present invention.

The present application is based on Japanese priority patent application No. 2009-230203 filed on Oct. 2, 2009, the entire contents of which are incorporated herein by reference.

### INDUSTRIAL APPLICABILITY

The present invention is applicable to portable equipments driven by a battery.

### EXPLANATION OF REFERENCE NUMERALS

100-100C portable equipment
100D DVD player
100E portable navigation device
100F controller
100G sound/voice data output device
100H reception device
110 specific process execution part
120 consumption current computing part
130 processing amount computing part
140 storage control part
150 notification part
160 setting part
170 playback time detection part
171 view possibility determination part
173 guide possibility determination part
200 battery pack
210 battery unit
220 monitor IC
230 protection IC
240 remaining amount detection part

What is claimed is:

1. A portable equipment that performs a predetermined process by being driven by a secondary battery, comprising:
a remaining amount detection part that detects a battery remaining amount of said secondary battery;
a consumption current computing part that computes an average value of a consumption current consumed to perform said predetermined process;
a processing amount computing part that computes an executable process amount of said predetermined process based on the battery remaining amount detected by said remaining amount detection part and the average value of the consumption current computed by said consumption current computing part; and
a notification part that notifies a user of said portable equipment of the executable process amount of said predetermined process computed by said process amount computing part.

2. The portable equipment as claimed in claim 1, wherein said notification part notifies of the executable process amount of said predetermined process by sound or voice.

3. The portable equipment as claimed in claim 1, wherein said notification part displays the executable process amount of said predetermined process on a display device.

4. A notification method performed by a portable equipment that performs a predetermined process by being driven by a secondary battery, comprising:
a remaining amount detecting step of detecting a battery remaining amount of said secondary battery;
a consumption current computing step of computing an average value of a consumption current consumed to perform said predetermined process;
a processing amount computing step of computing an executable process amount of said predetermined process based on the detected battery remaining amount and the computed average value of the consumption current; and
a notifying step of notifying a user of said portable equipment of the executable process amount of said predetermined process computed by said process amount computing part.

5. The notification method as claimed in claim 4, wherein said notification step notifies the executable process amount by sound or voice.

6. The notification method as claimed in claim 4, wherein said notification step displays the executable process amount of said predetermined process on a display device.

7. A computer readable notification program executed in a portable equipment that performs a predetermined process by being driven by a secondary battery, the program causing said portable equipment to execute:
a remaining amount detecting step of detecting a battery remaining amount of said secondary battery;
a consumption current computing step of computing an average value of a consumption current consumed to perform said predetermined process;
a processing amount computing step of computing an executable process amount of said predetermined process based on the detected battery remaining amount and the computed average value of the consumption current; and
a notifying step of notifying a user of said portable equipment of the executable process amount of said predetermined process computed by said process amount computing part.
